(19) United States
(12) Patent Application Publication
(10) Pub. No.: US 2026/0235947 A1
(43) Pub. Date: Aug. 13, 2026

(54) STABILIZATION OF A REPAIRED REGION OF AN OBJECT FOR LITHOGRAPHY

(71) Applicant: Carl Zeiss SMT GmbH, Oberkochen (DE)

(72) Inventors: Daniel Rhinow, Frankfurt (DE); Gerson Mette, Hoesbach (DE); Benjamin Herd, Hanau (DE); Laura Ahmels, Griesheim (DE); Hubertus Marbach, Grossostheim (DE); Christian Preischl, Aalen (DE); Bartholomaeus Szafranek, Ober-Ramstadt (DE); Patrick Salg, Darmstadt (DE); Eva Wirth, Darmstadt (DE); Tim Hadler, Stade (DE)

(21) Appl. No.: 19/576,530

(22) Filed: Mar. 24, 2026

Related U.S. Application Data
(63) Continuation of application No. PCT/EP2024/075251, filed on Sep. 10, 2024.

(30) Foreign Application Priority Data
Sep. 27, 2023 (DE) 102023209489.4

(51) Int. Cl. G03F 1/74

(52) U.S. Cl. CPC G03F 1/74

(57) ABSTRACT

The present invention relates inter alia to a method of passivating a repair region of a lithography mask, wherein the method comprises a) feeding in a passivation gas and b) directing a particle beam onto a passivation region of the mask, wherein the passivation region has at least one section outside the repair region.

### CROSS-REFERENCE TO RELATED APPLICATIONS

This application is a continuation of and claims benefit under 35 U.S.C. §120 from PCT application PCT/EP2024/075251, filed on Sep. 10, 2024, which claims priority from German patent application 102023209 489.4, entitled “Stabilisierung eines reparierten Bereichs eines Objekts für die Lithographie,” filed on Sep. 27, 2023. The entire contents of each of these earlier applications are incorporated herein by reference.

### TECHNICAL FIELD

The present invention relates to methods and devices for passivating a repaired region of a lithography mask.

### BACKGROUND

As a result of the growing integration density in the semiconductor industry, it is necessary for lithography masks to image structures of ever decreasing size onto wafers. In terms of lithography, the trend towards growing integration density is addressed by shifting the exposure wavelength of lithography apparatuses to ever shorter wavelengths.

Even though lithography masks are manufactured with very modern equipment and in a controlled environment, it may nevertheless be necessary for a finished mask to have sites or regions that do not meet the desired specifications (for example, with regard to absorbing and/or phase-shifting transmission properties of the mask in the sense of a, for example, opaque defect). It is also possible for defects to occur in the course of operation of a mask. These problems can be at least partly countered in that the mask in question is subjected to a repair process, for example, a particle beam-based repair, in which excess material is removed and/or missing material is deposited. In this context, DE 10 2020 120 884 A1, for example, discloses a method and an apparatus for etching a lithography mask.

With regard to the manufacture of modern lithography masks, it can be stated that, because of the increasing integration density and the associated decrease in size of the structures on the wafer, possible repairs of defects on the lithography mask also firstly become necessary more frequently and secondly become increasingly more complex. The basis of the increase in the complexity is that a structure size of possible defects and associated repair regions is being shifted to ever smaller structures. Both aspects can have the effect that an already repaired region degrades over time. This may especially also be the case when a further repair to the same mask is effected at another site that can possibly adversely affect the first repair site, for example, as a result of an unwanted and/or uncontrolled progression of a repair (e.g., etching).

The present invention is therefore based on the problem of providing methods and devices that can further improve the process of repairing lithography masks and other objects, especially masks with high integration density, for example, DUV and/or EUV masks, and enable a better-controllable repair process.

### SUMMARY

In one working example of the present invention, this problem is solved by methods according to Claims 1 and 3, and by devices according to Claims 25 and 27.

In a first embodiment, a method of passivating a repair region of a lithography mask may include a) feeding in a passivation gas and b) directing a particle beam onto a passivation region of the mask, wherein the passivation region has at least one section outside the repair region.

By virtue of the passivating according to the invention of the passivation region of the lithography mask, the passivated region in question can be stabilized, such that crosstalk from a repair to a different repair region on the mask does not entail any significant effects on the passivated region. This enables efficient suppression of unwanted progression of a repair operation in an already repaired region. It is thus possible by a passivation of the passivation region generally to enable an improved and more targeted repair of a lithography mask. In addition, for example, it is also possible to achieve elevated resistance to a reactive species during the process of production of the lithography mask and/or during cleaning of the lithography mask.

The inventors have recognized here that it can be of crucial importance for stabilization of a repair region that the passivation region does not coincide 1:1 with the repair region, but that at least sections of the passivation region are outside the repair region. This is because it is frequently the case that specifically (at least some) edges of the repair region are particularly prone to subsequent defects. This can be particularly advantageously prevented in that these edges are passivated reliably and over a large area, for example, in that the passivation region is not restricted exactly to the repair region but is (also) disposed outside the repair region.

The method may also comprise feeding in a repair gas before feeding in the passivation gas and directing the particle beam onto the repair region in the presence of the repair gas to repair a defect disposed in the repair region.

The feeding-in of a repair gas can initiate a selective etching process on the lithography mask with the aid of the particle beam. It is thus optionally possible to remove excess material from the lithography mask in the repair region (for example, by initiating an etching process). It is alternatively possible by the supply of a repair gas to enable selective deposition of material in the repair region of the lithography mask with the aid of the particle beam. In both cases, passivation according to the invention may follow the repair operation.

The repair gas can be fed in in the presence of a particle beam, which is preferably directed onto the repair region. Alternatively or additionally, the repair gas can be fed in before the particle beam is directed onto the repair region and/or between successive steps in which the particle beam is directed onto the repair region.

The passivation region may also have at least one section located in the repair region.

This may be beneficial to the passivation of the repair region, for example, because the edges of the repair region can be covered even better thereby. This can especially contribute to an improved repair outcome of a repair method according to the invention.

In a further embodiment, a method of repairing a lithography mask may comprise: a) a particle beam-based repair of a defect in a repair region of the mask in the presence of a repair gas and b) subsequent passivating of the repair region in a passivation region in the presence of a passivation gas, wherein the passivating is preferably effected in a particle beam-based manner.

The passivating according to the invention of a repair region, in analogy to the above remarks, may assist stabilization of the repair region or of an (adjoining) non-repaired region in an advantageous manner, such that it is possible to suppress disruption by further repair processes at adjacent sites. In addition, the subsequent passivating and hence a sequential separation of the repair and passivating operations enable passivating of the repair region, which does not significantly affect the repair process. Repair and passivation can be optimized independently of one another. This can contribute to an improved repair to the lithography mask.

The particle beam may take the form of a charged or uncharged beam. It may comprise massless particles and/or massy particles. In the case of a charged beam, the particle beam may be provided, for example, as an electron, ion or proton beam. Alternatively, it is possible that the particle beam (in the case of a charged particle beam) is provided, for example, as a neutron or photon beam or another suitable kind of beam.

The repair gas may include, for example, Xe and/or F, preferably XeF₂. In order to slow and/or to homogenize the repair process (preferably an etching process), the repair gas may additionally also contain H and/or O, preferably H₂O.

Passivation can mean a change (for example, by coverage) in a surface of the lithography mask in the passivation region such that a direct interaction of an atmosphere surrounding the lithography mask within which the repair and/or the passivation takes place can be suppressed by the material of the mask present in the passivation region.

In general, the passivation may be suitable for protecting at least part of the lithographic mask. For example, the passivation may serve to protect one or more materials of the mask. For example, the material of the mask may be part of a substrate layer of the mask. Additionally, or alternatively, the material of the mask may be part of an absorber layer of the mask. Additionally, or alternatively, the material may be part of a material deposited on the mask. In other words, passivation of at least a portion of the lithographic mask may result in protection of the substrate material and/or the absorber material and/or a deposited material. Protection of at least a portion of the lithographic mask may comprise (at least partial) suppression of (direct) interaction of an atmosphere surrounding the lithographic mask, within which the repair and/or passivation takes place, with the material of the mask contained in the passivation region.

The passivation of at least a portion of the mask may be arranged such that the resulting protection comprises protection from high energy radiation. For example, the protection from high energy radiation may comprise protection from high energy electromagnetic radiation used with DUV and/or EUV masks.

Additionally, or alternatively, the passivation of at least a portion of the mask may be arranged such that the resulting protection comprises protection from cleaning of at least a portion of the lithographic mask. The cleaning of the at least part of the mask may be based on at least one cleaning procedure. Specifically, the cleaning and/or cleaning procedure may be designed to remove unwanted materials on the mask. For example, the cleaning and/or the cleaning procedure may comprise a removal and/or a removal of excess material, i.e., a defect. In particular, the defect may be a dirt and/or dust particle. The cleaning and/or the cleaning procedure may comprise an etching process. The etching process can be designed in such a way that it enables targeted and defined removal of the excess material.

In general, the passivation of at least part of the lithographic mask may be designed such that a defect present on the lithographic mask, for example, the presence of excess material, is not (completely) passivated by the passivation. For example, the passivation can be designed in such a way that at least part of the defect is not passivated. In particular, the passivation can be designed in such a way that the passivation layer is not deposited in an area that completely covers the (not yet repaired) defect. In other words, a surface of the defect is not completely covered with the passivation layer. For example, the passivation layer may not be deposited along the entire surface of the (existing) defect.

Additionally, or alternatively, the passivation of at least part of the mask may be arranged such that the resulting protection comprises protection against (undesired) oxidation of at least one material of the lithographic mask. For example, the protection against (undesired) oxidation of at least one material may comprise protection against contact with at least one oxidizing material. An oxidizing material may comprise a material and/or an element and/or a molecule that may contribute to oxidation of materials of the lithographic mask and/or promotes oxidation of materials of the lithographic mask. For example, the oxidizing material may comprise a gas. In particular, the oxidizing material may comprise fluorine.

For example, the passivation step can be configured such that the passivation region withstands at least 5, 10, 15 or at least 20 subsequent etching operations on the same sample, where the etching operations may be particle beam-based etching operations on, for example, in each case a repair region having an area of 0.25 µm² present on the same sample where material with a thickness in the range from 10 nm to 150 nm is removed.

The passivation region may fully cover the repair region.

This can enable complete passivation of the repair region, such that a progressive unwanted repair operation across the entire repair region can be prevented.

The passivation region may have a greater area than the repair region.

This can firstly enable an integral overlap of the sections of the passivation region. It is thus possible to enable generally increased stability of the passivation region.

The passivation region may extend at least partly along an edge section of the repair region.

In this way, the edge section of the repair region in particular may be stabilized after the repair operation. This may be particularly advantageous since an edge section can be considered to be particularly sensitive to progression of the repair process. It is thus possible to suppress unwanted progression of the repair process along the edge region of the repair region.

The repair region may be at least partly bounded from a non-repaired region by a border and/or a circumferential edge.

By scanning the particle beam across the repair region, the repair region may be sharply delimited from a non-repaired region (in which no scanning by use of a particle beam took place). In such a case, a defined border may arise between the repair region and a non-repaired region. Such a border may be formed, for example, by an absorbing and/or phase-shifting pattern element of the mask.

The passivation region may at least partly include the border and/or the circumferential edge.

In this way, in particular, progression of the repair operation beyond the border and/or the circumferential edge (for example, into a non-repaired region) can be achieved via controlled stabilization of the border and/or the circumferential edge. The border and/or the circumferential edge may be completely contained in the passivation region.

The passivation region may have at least one section having a width between 2 and 150 nm that extends beyond the border and/or the circumferential edge. The section may extend, for example, completely along the border and/or completely along the circumferential edge.

In this way, it is possible to enable reliable protection of the passivation region by the border and/or the circumferential edge. In some cases, by virtue of a greater extent of the passivation region beyond the border and/or the circumferential edge, it is possible to achieve elevated stabilization of the region surrounding the repair region in that, for example, a larger section of the non-repaired region is prophylactically protected by passivation from unwanted progression of the repair operation beyond the repair region.

The passivation region may have at least one section having a width of 2 to 150 nm that extends into the border and/or the circumferential edge.

Analogously to the aspects described above, this can contribute to particularly lasting passivation of the repair region. The border and/or the circumferential edge, which are particularly prone, can thus be comprehensively protected.

The method may also be set up such that there is no passivation in at least one section of the repair region.

The at least one non-passivated section may include, for example, a center of the repair region. It may include, for example, essentially the entire repair region apart from a section that extends along an edge of the repair region as described herein.

It is thus possible for a concentration in the passivation operation to reach the border region and/or circumferential region which tends to be somewhat critical for progression of the repair process. This can contribute to a quicker and less costly passivating operation and assist a more efficient repair to a lithography mask overall.

The passivation gas may include a first component including Si and/or O.

The presence of Si and O in some preferred cases in the passivation region can result in formation of SiO₂ and hence prevent later contact with a process gas.

The first component of the passivation gas may include a tetraethoxysilane, TEOS.

This can assist particularly effective passivation.

The passivation gas may include a second component comprising N and/or O, preferably NO₂.

This can contribute to elevated stability of the passivated region. It has been found that this can reduce the carbon content of an Si- and O-containing passivation layer that can form, for example, as a result of deposition with TEOS. This can be effected, for example, by an oxidizing effect of the NO₂. This may assist, for example, an elevated stability of the passivation region, for example with respect to a process gas during the repair operation (repair gas), with respect to a reactive species during the process for production of the lithography mask and/or during cleaning of the lithography mask. In addition, the presence of the second component may contribute to a reduction in the amount of material required for the passivation. This can contribute to more efficient and less costly passivation. In addition, the reduced amount of material can contribute to a reduction in the effects of the passivation on the optical properties of the mask. In this way, it is possible to suppress any unwanted influence, possibly caused by the passivation, on the optical properties of the mask (for example, an unwanted increase in the absorption properties of the mask).

The defect may include a defect with excess material of an absorbing and/or phase-shifting material. For example, the defect may be caused by a soil particle. It is alternatively possible that, for example, a pattern element is disposed beyond its envisaged geometry. The defect material and/or the material of the pattern element may include, for example, Ta, preferably TaN. The defect may be an opaque defect.

The repair allows the lithography mask, in an environment of the repair region, to be brought into the range of the specification needed for functioning.

A repair process, which is preferably provided in the form of an etching process (for example, in the presence of an opaque defect), can make it possible to remove the excess material on the lithography mask in a controlled and defined manner. It is thus possible to eliminate the unwanted absorption properties and/or phase-shifting properties associated with the excess material.

In the presence of the particle beam and the passivation gas, it is possible to deposit a passivation layer in the passivation region which is preferably Si- and/or O-containing.

Deposition of a passivation layer in the passivation region can achieve physical coverage of the passivation region. This may enable (complete) physical coverage of the passivation region by a volume in which repair gases may be present, which could lead to unwanted etching in the case of interaction with a material in the repair region and/or the non-repaired region.

The deposited layer may include or be a SiₓO_{y}C_{z} layer.

This may enable particularly effective and preferred passivation of the passivation region. Preferably, z < x and/or z < y, such that the characteristics come as close as possible to SiO₂.

The passivation layer may be configured such that the deposition of the passivation layer does not significantly affect the specification of the mask.

In particular, the passivation layer may be formed such that it does not significantly influence the optical properties of the lithography mask in the passivation region with regard to the absorbing and/or phase-shifting properties thereof by comparison with a region of the lithography mask which is not covered by the passivation.

There is insignificant influencing of the specification of the mask when the variance caused by the passivation layer is sufficiently small that the mask still meets the specifications even thereafter. It is alternatively conceivable that the (likely) changes resulting from the passivation are already taken into account in the repair, such that the mask is on spec at least overall after repair and passivation.

A thickness of the passivation layer may be in a range from 100 pm to 35 nm, preferably in a range from 1 nm to 30 nm or 2 nm to 20 nm, and more preferably in a range from 2 nm to 10 nm.

The thickness of the passivation layer may be essentially constant over the passivation region. Alternatively, it is possible that the thickness of the passivation layer is subject to a variation across the passivation region and the thickness of the passivation layer is in the abovementioned range on average.

The deposited passivation layer may have a complex refractive index having a smaller real part and/or imaginary part than a real part and/or imaginary part of a complex refractive index of a material of a pattern element of the mask.

The real part and/or imaginary part of the complex refractive index of the passivation layer may be smaller, for example, by a factor of 1.5 to 10 than a real part and/or imaginary part of the complex refractive index of the material of the pattern element of the mask.

This can contribute to a lack of any significant influence of the presence of the passivation layer on the absorption properties and/or the phase-shifting properties of the lithography mask.

The pattern element may, for example, be a “lines-and-spaces” pattern.

The deposited passivation layer may be provided such that it is not significantly affected by at least five, preferably at least ten, further repair cycles on the lithography mask (with respect to defects elsewhere on the mask).

In this way, it can be ensured that a particular number of further repair cycles on the mask can suppress any unwanted influence on the passivation region (for example, by crosstalk of the further repair cycles on the passivation region).

The functions described above may be implemented in hardware, processor-executed software (e.g., as a computer program), firmware or any desired combination thereof. If they are implemented in software executed by a processor, the functions may be stored on a computer-readable medium as one or more instructions or codes or be transmitted by way thereof. The functions described here may be implemented, for example, with the aid of software executed by a processor, hardware, firmware, hard-wiring or combinations thereof. Features which implement functions may also be arranged physically at different positions, including a distribution, such that portions of the functions are implemented at different physical locations.

In a further embodiment, a device for passivating a repair region of a lithography mask may include: a) means of feeding in a passivation gas and b) means of directing a particle beam onto a passivation region, wherein the passivation region has at least one section outside the repair region.

In a further embodiment, a device for repairing a lithography mask may comprise: a) means of particle beam-based repair of a defect in a repair region of the mask in the presence of a repair gas and b) means of subsequently passivating the repair region in a passivation region and in the presence of a passivation gas, wherein the passivating is preferably effected in a particle beam-based manner.

The device may further comprise means of automatic execution of the subsequent passivation after the particle beam-based repair has ended.

It is thus possible in an advantageous manner to ensure direct passivation of at least a portion of a repair region after the repair operation in order thus to suppress unwanted progression of the repair operation by presence of the repair gas. This can contribute to greater control over the repair process.

The above devices may also comprise means of determining the passivation region based on an extent of the repair region.

The means may comprise algorithms set up to (automatically) determine, based on knowledge of the repair region, an optimal geometry of the passivation region. For example, it is possible to automatically define a passivation region described herein that completely covers the repair region and/or runs completely along a border or a circumferential edge of the repair region.

Additionally or alternatively, the means may comprise a (graphic) user interface (GUI) that can make it possible for a user of the device to define a region to be passivated on the lithography mask by interaction with the graphic user interface. This may enable, for example, selection between the alternatives of “complete coverage” or “edge region only” of the repair region. Additionally or alternatively, the GUI may also define a width of an edge outside and/or within the repair region (optionally running along a border and/or around the repair region).

The devices may further comprise means of (automatic) execution of the method according to any of the preceding claims.

The devices may also comprise the aforementioned computer program.

A further aspect of the present invention relates to a method of repairing and/or examining a lithography mask. The method may comprise particle beam-based passivation of a reference marking.

This can contribute in an advantageous manner to assurance of a more stable reference marking during the repair. For example, a reference marking may be generated on the mask (or more generally: sample), for example, in a particle beam-based manner. Subsequently, the reference marking may be passivated. This aspect may also be combined with the further aspects of the invention that are described herein. The passivation region may be configured analogously in relation to the region in which the reference marking is disposed, as described with regard to a repair region herein.

Although the invention is elucidated predominantly with reference to lithography masks, the various aspects of the invention are also applicable to other objects, for example, substrates, wafers, mask blanks, etc., or more generally: samples.

### DESCRIPTION OF DRAWINGS

The detailed description that follows describes currently preferred exemplary embodiments of the invention with reference to the drawings, wherein:

FIGS. 1A-1D: show an illustration of the process steps of a repair process according to the invention and a passivation process on a lithography mask in a section view;

FIGS. 2A-2D: show an exemplary illustration of a passivation in a “lines-and-spaces” pattern of a lithography mask in a top view;

FIGS. 3A-3C: show a scanning electron microscope (SEM) image of an illustrative repair region of a lithography mask and illustrative (geometric) configurations of a passivation region;

FIGS. 4A-4B: show a comparison of the effects of the width of a passivation region on the stability thereof;

FIGS. 5A-5B: show illustrative SEM images of a non-passivated repair region;

FIG. 6: shows illustrative SEM images with passivated repair regions;

FIGS. 7A-7B: show an SEM image of a “lines-and-spaces” pattern of a lithography mask in the presence or absence of a passivation layer;

FIGS. 8A-8B: show illustrative SEM images of a partly repaired defect for illustration of a passivating operation.

### DETAILED DESCRIPTION

Currently preferred embodiments of devices according to the invention and of a method according to the invention for passivation of a region of a lithography mask are elucidated in detail hereinafter. However, the use of the apparatuses according to the invention and of the method according to the invention is not restricted to the examples discussed below. Instead, these can generally be used for passivation of a lithography mask.

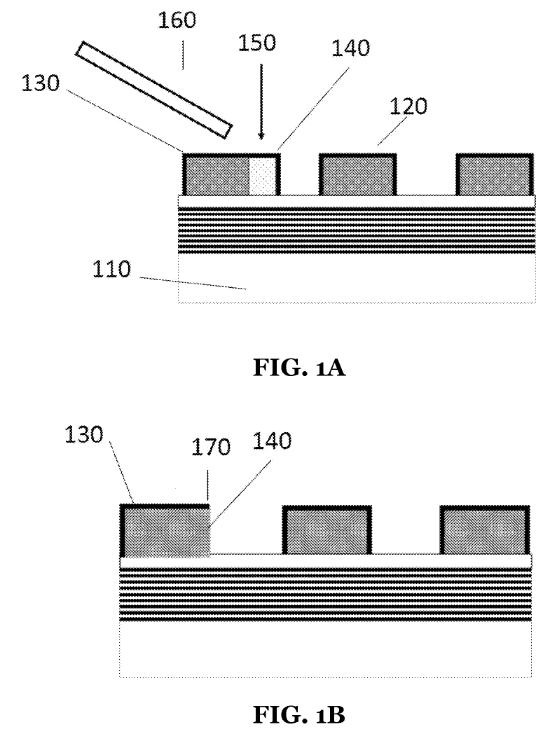

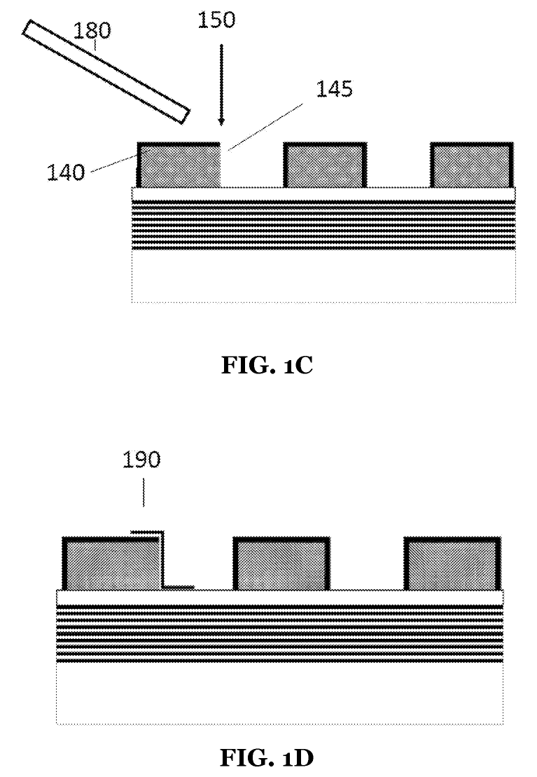

FIGS. 1A-1D show illustrative process steps in a repair and a passivation process on a lithography mask 110. The mask 110 may, for example, be an EUV mask.

FIG. 1A shows an illustrative repair operation on the mask 110. Applied by way of example on the top side of the mask 110 are several absorbing and/or phase-shifting elements 120 (in one example, these may be parallel lines of a so-called “lines-and-spaces” structure). The absorbing and/or phase-shifting elements 120 may preferably have a layer manufactured from a material comprising Ta, preferably TaN. This layer may form the majority of the elements 120, for example, have a thickness greater than 50% of the thickness of the elements 120.

The elements 120 may be disposed, for example, on an outer layer of the mask 110 that may include ruthenium, for example. Beneath the outer layer may be disposed an Mo-Si stack that may be present on a substrate of the mask 110.

A repair process is implemented by way of example on the selected absorbing or phase-shifting element 130 (far left in FIG. 1A) in order to remove the absorbing or phase-shifting elements 130 in the repair region 140 (in other examples, it is also possible merely to reduce the height).

For this purpose, a particle beam 150 is directed onto the repair region 140 of the absorbing and/or phase-shifting element 130. Typically, the particle beam 150 is focused such that it can be applied locally, for example, with a diameter of < 1 nm. The particle beam 150 may comprise electrons, for example. The electrons may be accelerated, for example, with an acceleration voltage of 0.01 kV to 30 kV. Typical currents of the particle beam (for example, an electron beam) may, for example, be in the range from 0 to 300 nA, 3 pA to 20 nA, 10 pA to 300 nA, or 1 pA to 150 pA.

The particle beam 150 is preferably directed during and/or after feeding-in of a repair gas 160. In a preferred embodiment of the invention, the repair gas 160 may contain, for example, Xe and/or F, preferably XeF₂. In some illustrative cases, the repair gas 160 may also contain H₂O in order to achieve slowing and hence better control over the repair operation, which can contribute to a more homogeneous progression of etching (compared to a repair without H₂O). Alternatively or additionally, it is possible that the repair gas contains NO₂, for example, in addition to XeF₂ and H₂O.

The interaction of the particle beam 150 and of the repair gas 160 can lead to particle beam-induced etching of the absorbing and/or phase-shifting element 130 in the repair region 140 and hence the thickness of the absorbing and/or phase-shifting element 130 can be reduced. This can lower the absorbing and/or phase-shifting properties of the treated absorbing and/or phase-shifting element 130 in the repair region 140 in a controlled manner.

FIG. 1B shows the repair region 140 on the absorbing and/or phase-shifting element 130 after the repair operation has ended.

An interaction of particle beam 150 and the repair gas 160 fed in (containing H₂O inter alia) can result in deposition of a passivation layer in the repair region 140. The passivation layer may comprise here Ta₂O₅.

Even though a passivation layer 170 can therefore form in principle in the repair region 140, the formation is only incomplete in some cases and not to a satisfactory degree. Especially in the case of tantalum-containing elements 120/130, problems can occur here, in particular when they are disposed on a ruthenium-containing outer layer.

For instance, it has been recognized that, in some cases, rather than a continuous Ta₂O₅-containing layer, a layer containing defect sites can form, which can have the effect that the material of the lithography mask which is present in the repair region 140 is not fully covered with the passivation layer 170.

In some cases, the defect sites may contain TaOₓF_{y}. This can lead to the favored release of reactive F-containing species, which can in turn promote unwanted progression of the repair process.

Since the repair region 140 in the present case is merely an inadequately passivated region, the presence of residues of the repair gas 160 can lead to further progression of etching in a non-repaired region of the absorbing and/or phase-shifting element 130. This may firstly comprise etching of a section of the absorbing and/or phase-shifting element 130 that was not previously part of the repair process (or onto which the particle beam 150 has not previously been directed) or may comprise further etching of the repair region 140 that has already been processed with the particle beam 150, such that a further (unwanted) reduction in thickness of the absorbing and/or phase-shifting element 130 in the region of the repair region 140 or progression of the etching operation into a non-repaired region can be effected.

Controlled post-passivation by directing the particle beam 150 again and feeding in the repair gas 160 again (for example, containing H₂O) does not usually lead to sufficient passivation either. This is attributed to the fact that the feeding-in of H₂O, for example, especially when the defect sites contain TaOₓF_{y} species, can lead to formation of reactive species, which can promote unwanted progression of the repair operation in the repair region 140 (or beyond it).

Additionally or alternatively, it may be possible that XeF₂ gas has remained in the atmosphere in which the above-described repair operation has been executed, which can find use by way of example as repair gas 160. This can have the effect that the remaining repair gas, because of the reactive properties thereof, contributes to further progression of the repair process in the repair region 140 (for example, in the region of the defect sites) and/or a previously non-repaired region. Additionally or alternatively, interaction with H₂O can be used to contribute to the formation of reactive HF.

In order to suppress the problems described in relation to FIG. 1B, FIG. 1C shows a passivation process according to one aspect of the present invention.

FIG. 1C shows directing of the particle beam 150 onto at least a section of the repair region 140, i.e., a passivation region 145.

In addition, a passivation gas 180 is fed to the operation. The passivation gas may correspond to the repair gas in at least one of its constituents. Alternatively, it is possible that the passivation gas is completely different from the repair gas.

FIG. 1D shows, by way of example, a deposited passivation layer 190 which is deposited by interaction of the particle beam 150 and the passivation gas 180 and which completely covers the passivation region 145. The passivation layer 190 preferably has both a section in the repair region 140 and outside the repair region 140. In addition, a border of the element 130 may be completely covered by the passivation layer 190. For instance, the section of the passivation region in the repair region (running horizontally in FIG. 1 on the outer layer of the mask) may be connected to the section outside the repair region (horizontally on the element 130 in FIG. 1) by a section of the passivation layer 190 (running vertically in FIG. 1).

As has already been described above, the passivation gas 180 may be NO₂-containing. This can contribute to a reduction in carbon content in the deposited matter and hence lead to a decrease in the thickness of the passivation layer deposited (by comparison with an achieved thickness of the passivation layer in the absence of an NO₂-containing passivation gas 180 having similar stabilizing action).

It was possible to determine empirically that at least about 25 passivation passes are required to achieve detectable stabilization. A passivation pass in this context means a single scan of a passivation region with a particle beam and in the presence of a passivation gas in order to deposit a passivation layer in the passivation region. The passivation pass can be performed repeatedly in order to increase the effects induced by the passivating operation. Further repair operations can be conducted between the passivation passes.

Preferred results were achievable after about 200 passivation passes. An increase in the number of passivation passes executed from, for example, 200 to 500 could slightly further increase the stability, while a further increase in the number of passivation passes executed from, for example, 500 to 1000 did no longer cause any substantial improvement in stabilization.

The thickness of the passivation layer deposited may be ascertained, for example, by atomic force microscopy (AFM) images and is, for example, about 1.5 nm to 3.5 nm for 200 passivation cycles, while it is about 5.5-6.5 nm with 500 passivation cycles.

Moreover, based on the passivation passes conducted and subsequent measurement of thickness of the respectively deposited passivation layer, the correlation between the number of passivation passes and passivation layer thickness deposited was ascertainable. It was possible to determine here that the thickness of the passivation layer is typically proportional to the number of passivation passes performed. It was possible to determine here experimentally that ten passivation passes can achieve deposition of a passivation layer having a thickness of about 75 to 150 pm.

Illustrative thicknesses of the passivation layer are accordingly, for example, 100 pm to 30 nm, preferably 150 pm to 15 nm or 200 pm to 5 nm.

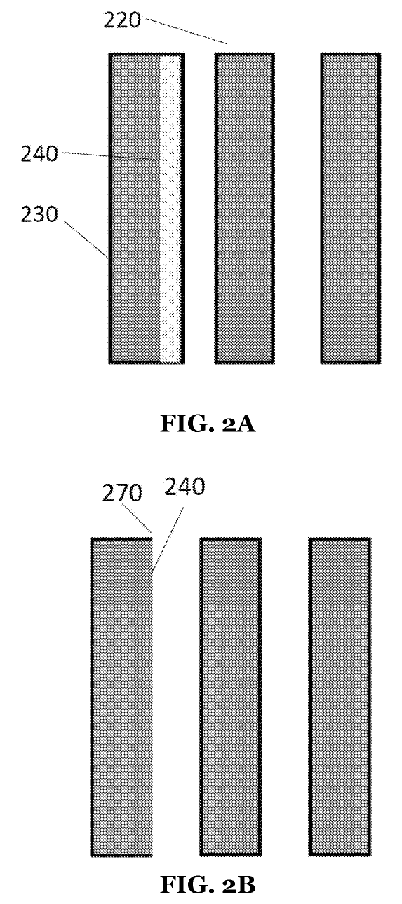

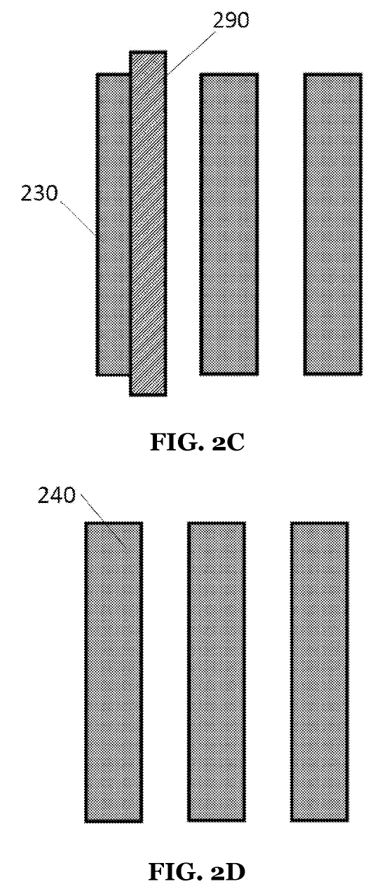

FIGS. 2A-2D show an illustrative passivation pass on a “lines-and-spaces” pattern of a lithography mask in a top view in one aspect of the present invention. The elements discussed with regard to FIGS. 2A-2D (for example, absorbing and/or phase-shifting elements 220/240, repair region 240, etc.) correspond here to the respective corresponding elements that have already been described above in relation to FIGS. 1A-1D.

FIG. 2A shows a border of a repaired absorbing and/or phase-shifting element 230 of a lithography mask that is disposed alongside absorbing and/or phase-shifting elements 220 that have not been repaired (and are not in need of repair).

FIG. 2B shows the situation after the repair operation.

FIG. 2C shows an illustrative application of a passivation layer 290 to the repair region 240 with a section that does not extend in the repair region 240. The passivation region may extend beyond the repair region in at least two dimensions. In the example of FIG. 2, the passivation region extends beyond the repair region both in a horizontal direction (at right angles to the progression of the “lines”) and in a vertical direction.

FIG. 2D shows the illustrative (long-term) effects of applying the passivation layer 290 to the absorbing and/or phase-shifting element 230. As shown in FIG. 2D, the applying of the passivation layer 290 leads to stabilization of the absorbing and/or phase-shifting element 230, especially in the region of the repair region 240. In this way, it is possible to achieve stabilization of the repair region 240 and suppress unwanted and/or uncontrolled progression of the repair process.

By applying the passivation layer 290 in the repair region 240, it is thus possible to achieve stability of the repair region 240 against (unwanted) progression of the etching operation, as can also be achieved in the case of non-repaired regions of a lithography mask.

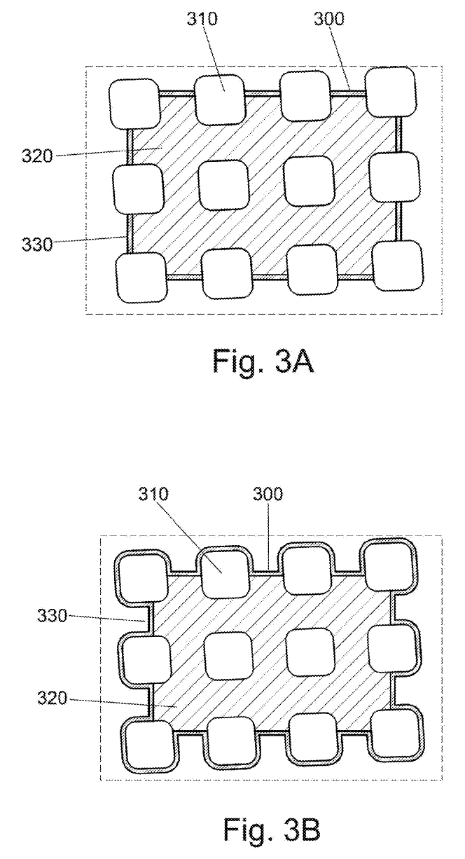

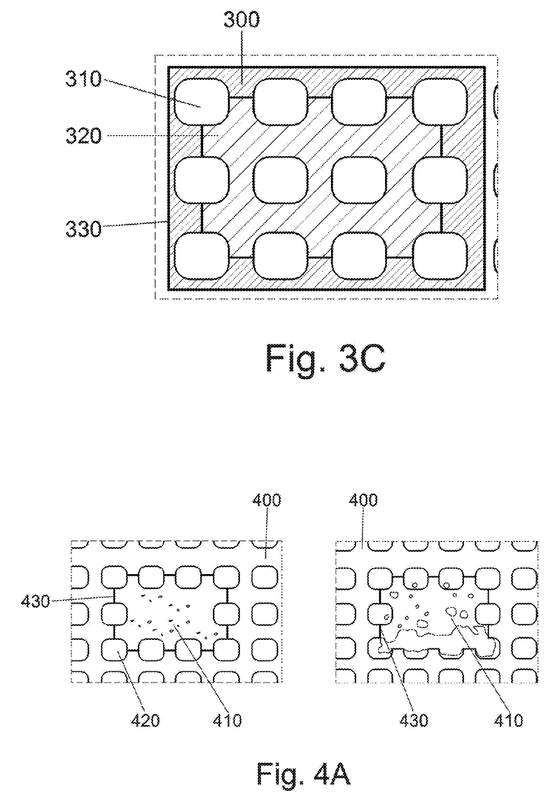

FIGS. 3A-3C show possible configurations of a passivation region around a repair region in the presence of a regular arrangement (in top view) of so-called “contact holes” (CH) disposed on a lithography mask.

CHs mean holes in the substrate of a lithography mask that can be obtained, for example, by an etching operation and extend over one or more layers of a lithography mask and can serve to bond one or more layers of a lithography mask to one another.

FIG. 3A shows an SEM image of a lithography mask 300 having a regular pattern of CHs 310. For test purposes, the material in the repair region 320 is to be completely removed therein. This is to be followed by a passivation.

In the passivating operation, it is possible, according to FIG. 3A, to provide the passivation region 330 merely around the border created by the removal of material. The already existing borders of the CHs 310 disposed on the outer sides of the repair region 320 and the connecting lines between these CHs 310 themselves are not to be passivated as well.

In this working example, there is no areal passivation of the repair region 320.

This enables rapid and inexpensive passivating of an outer region of the repair region 320, which tends to be able to be considered the most sensitive to progression of a repair operation.

The repair region 330 in this example is linear in sections, where the lines run centrally along the borders created by the removal process, and may have a variable width (e.g., ± 2 nm to ± 150 nm, e.g., ± 4 nm to ± 100 nm or ± 8 nm to ± 80 nm, in each case viewed essentially from the border).

FIG. 3B shows a further SEM image of an illustrative repair region 320 that may be configured as described with regard to FIG. 3A.

According to FIG. 3B, the position of the passivation region 320 is not just linear in sections along the borders formed by the removal of material. It is also in a linear position around the already existing borders of the CHs 310 that lie in the edge region of the repair region 320. The result is a passivation region in the form of a line running in the form of crenellations around the repair region (which may have widths as described with regard to FIG. 3A).

This may contribute, analogously to the observations relating to FIG. 3A, to rapid and inexpensive and hence efficient stabilization of at least one section of a repair region 320 and at least one section of a non-repaired region of the lithography mask 300. In addition, the non-repaired borders of the CHs 310 may also be passivated as well in order to reduce the risk that these may be attacked in processes as described herein subsequent to the actual repair. In this working example, there is no areal passivation of the repair region 320.

FIG. 3C shows a further SEM image of a lithography mask 300 (in top view) having a regular pattern of CHs 310 and a further possible passivation geometry.

According to FIG. 3C, it is possible to select the passivation geometry such that the repair region 320 is covered completely by the passivation region 330. In addition, the passivation region 330 additionally has an additional circumferential edge such that the CHs 310 at the edge of the repair region 320 are also fully covered. The edge may additionally extend slightly beyond the edges of the CHs 310.

This can contribute to particularly stable passivation of the repair region 320.

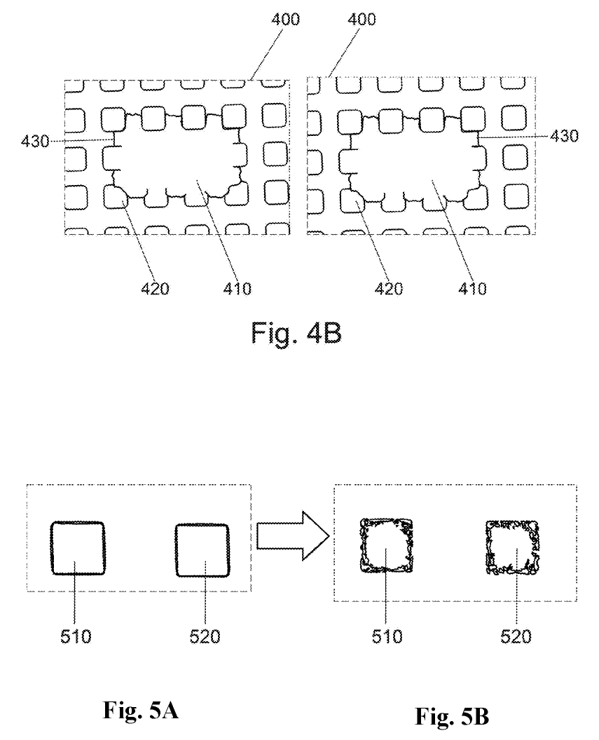

FIGS. 4A and 4B show a comparison of the effects of the width of the passivation region along a circumferential edge of a repair region (as discussed herein) for two possible extents of ± 4 nm (FIG. 4A) and of ± 10 nm (FIG. 4B) on the stability of the resultant passivation.

FIG. 4A (on the left) shows an SEM image (analogously to be SEM images in FIGS. 3A-3C) of a mask 400, where, for test purposes, an etching operation has been performed in a repair region 410 (comprising inter alia CHs 420, such as CHs 310) of the mask 400.

The etching process performed led to the formation of borders 430 that divide the repair region 410 from a non-repaired region of the mask 400.

In addition, the repair region 410, according to the observations relating to FIG. 3A, has been provided with a passivation layer, where the passivation layer has been deposited around the border 430 with a width of ± 4 nm.

FIG. 4A (on the right) shows the repair region 410 (as described above) that has been provided with a passivation layer after 22 further illustrative repair cycles have been conducted on the mask 400.

FIG. 4A (on the right), compared to FIG. 4A (on the left), shows clearly visible degradation of the mask 400, visible inter alia in the region of the border 430. In addition, the repair region 410, in FIG. 4A (on the right), shows a marble-like pattern which is likewise attributable to degradation of the mask at the site of the repair region 410.

By contrast, FIG. 4B (on the left) likewise shows an SEM image of a mask 400, in analogy to the SEM images of FIG. 4A, on which an etching operation has likewise been undertaken in a repair region 410.

By contrast with the observations relating to FIG. 4A, in the case shown in FIG. 4B, a passivation layer having a width of ± 10 nm has been applied to the mask 400 around the border 430.

FIG. 4B (on the right), by contrast, shows the repair region 420 that has been provided with a passivation layer after 22 further repair cycles have been performed on the mask 400.

By direct comparison between FIG. 4A (on the right) and FIG. 4B (on the right), it can be stated that a broader passivation layer (i.e., ± 10 nm (FIG. 4A) rather than ± 4 nm (FIG. 4B)) leads to improved stability of the repair region 410 or the border 430 and the passivation region applied around these.

A systematically conducted characterization of the stability of a deposited passivation layer depending on the chosen width was able to show here that a higher width generally (within certain limits) leads to a passivation layer having longer-term stability, meaning that the passivation layer can withstand the effects of any repair gas present for a longer period or a higher number of repair cycles performed elsewhere on the mask (without significant degradation).

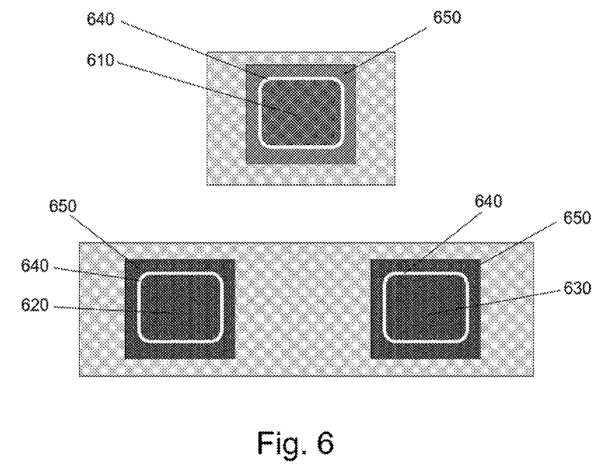

However, it was also found that, in some examples, a broader passivation region than ± 10 nm no longer leads to any significant further improvement. Nor does areal passivation (as elucidated in relation to FIG. 6) lead to a distinctly better result in some examples. Even with a passivation region of ± 7 nm, good results could already be achieved. It was likewise found however that a passivation region having a width of less than ± 4 nm usually leads to distinct degradation of the mask in the repair region 410 and at the border 430.

Illustrative widths of the repair region are thus at least ± 4 nm, while, for example, ± 40 nm may be a possible practicable upper limit in order that the duration of the passivation process remains minimal. In some cases, the widths may be in the range from ± 5 nm to ± 20 nm.

For example, a width of the passivation region along a border of a repair region may be chosen such that the passivation region withstands at least 5, 10, 15 or at least 20 subsequent etching operations on the same sample, where the etching operations may be particle beam-based etching operations on, for example, in each case a repair region having an area of 0.25 µm² present on the same sample where material with a thickness in the range from 10 nm to 150 nm is removed.

For example, a thickness of a passivation region may be chosen such that the passivation region withstands at least 5, 10, 15 or at least 20 subsequent etching operations on the same sample, where the etching operations may be particle beam-based etching operations on, for example, in each case a repair region having an area of 0.1 µm² to 1 µm², e.g. 0.25 µm², present on the same sample where material with a thickness in the range from 10 nm to 150 nm, e.g., 100 nm, is removed.

FIGS. 5A and 5B show contrasting SEM images of a lithography mask immediately after (FIG. 5A) and one day after (FIG. 5B) an illustrative etching operation that was utilized to create openings 510 and 520 in a lithography mask at two sites by material removal, in order to characterize the passivation method described herein.

FIG. 5A shows the openings 510 and 520 (immediately) after conclusion of the removal or etching operation, which was conducted in an electron beam-based manner. The etching depth extended down to an etch stop layer (formed in the present example by an outer Ru layer).

FIG. 5B shows the openings 510 and 520 as described in relation to FIG. 5A, but on a day after the day of repair.

As apparent from FIG. 5B, the openings 510 and 520 show degradation of the outer appearance, which results from the absent passivation layer at these openings 510 and 520.

FIG. 6 shows various openings 610-630 that have been created in a mask by electron beam-based etching. In the present example, this was effected by etching of a tantalum-containing layer down to an etch stop layer (formed in the present example by an outer ruthenium-containing layer).

After the etching, however, a passivation step was conducted here in each case, by contrast with FIGS. 5A and 5B. The openings 610-630 were passivated by use of an electron beam and by use of TEOS gas and NO₂ as additional gas with a different number of passes.

The images of the openings 610-630 were likewise created after one day. No noticeable degradation of the openings is apparent.

The openings were passivated for different periods of time. The opening 610 was passivated with 200 passivation passes. Opening 620 was passivated by use of 500 passivation passes. Opening 630 was passivated by use of 1000 passivation passes.

The openings 610-630 thus created have illustrative dimensions of 400 nm x 400 nm and form the repair region. The openings 610-630 are each surrounded by a border 640 that delimits the repair region from a non-repaired region. The borders 640 are each surrounded (symmetrically) by a passivation region 650. The dimensions of the passivation region that are shown by way of example are here 600 nm x 600 nm, so as to result in a width of the passivation region along the borders 640 of at least about ± 100 nm. In some examples, the passivation region within the repair region is configured differently and covers the latter completely.

Following the openings 610-630, it is found that an increasing number of passivation cycles performed leads to an increase in the thickness of the passivation layer 650. This is shown by increasing darkening of the passivation region 650.

The use of TEOS can advantageously favour passivation of the environment of a repair region in that, for example, in particular chemisorbed F, HF and/or XeF₂ is inactivated by a chemical reaction with TEOS molecules or species that are formed from TEOS in an electron beam-induced manner, and/or in that fluorine compounds are displaced by physisorption and/or chemisorption of TEOS molecules. In addition, the use of TEOS can achieve inactivation of at least one TaOₓF_{y} species that could otherwise function as a source of reactive fluorine compounds and could contribute to the release of reactive HF.

In some examples, the amount of SiₓO_{y}C_{z}, for example, deposited at the repaired site by the passivation can locally alter the optical properties of the lithography mask. The change in the optical properties may be proportional to the thickness and area of the deposited passivation layer and may be dependent on the complex refractive index of the materials used for the deposition of the passivation layer. In particular, the absorption for EUV light may be altered. Furthermore, the deposited passivation layer can alter the phase-shifting properties of the mask. The thickness of the deposited layer may therefore be chosen such that the optical properties of the repaired site (absorption, phase shift) do not change beyond a predefined limit.

If the amount of deposited material needed for passivation exceeds a limit, it may become necessary to include the effect of the deposited material and hence the thickness of the passivation layer in the planning of the passivating operation. For example, by means of a repair operation preceding the passivation, it is possible to specifically remove more material than necessary for the reconstruction of the site in question in order to bring the lithography mask on spec. This area additionally exposed by the particle beam may be specified in pixels, for example in the form of a bias, and comprise an “artificial” extension of the repair operation to a material section of the lithography mask that need not be part of the repair operation in terms of its properties. The material deposited for passivation thus contributes to the reconstruction of the border. The desired optical properties of the repair region then arise from the combination of the optical properties of the repair region and the optical properties of the deposited passivation layer.

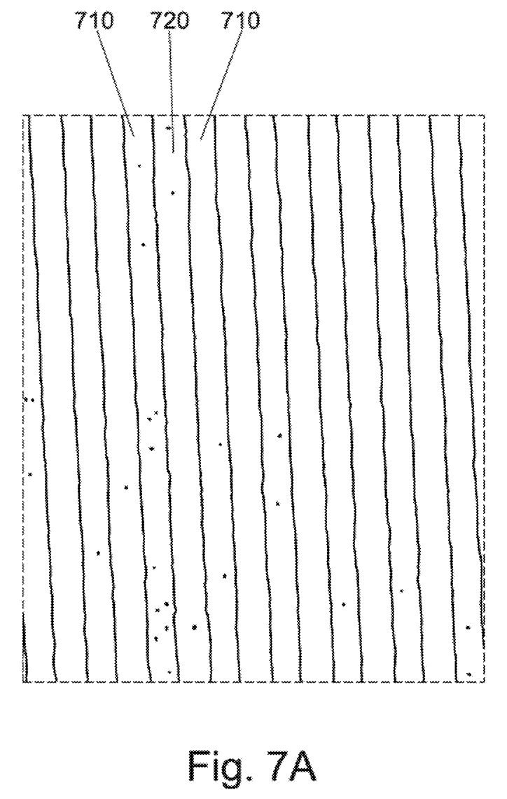

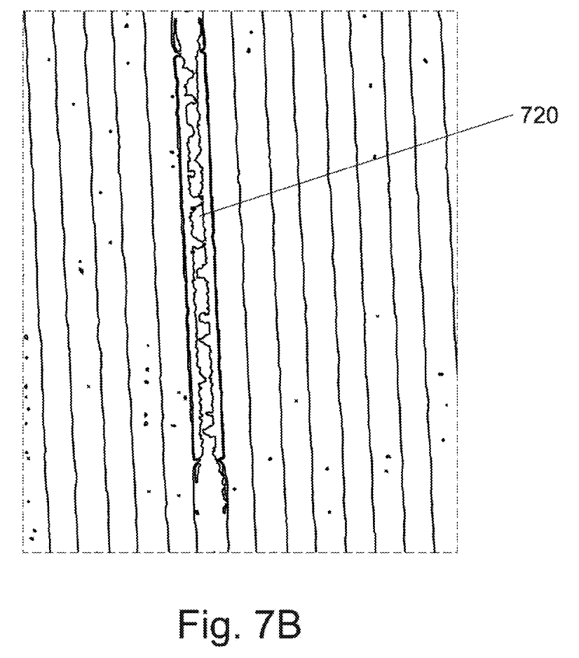

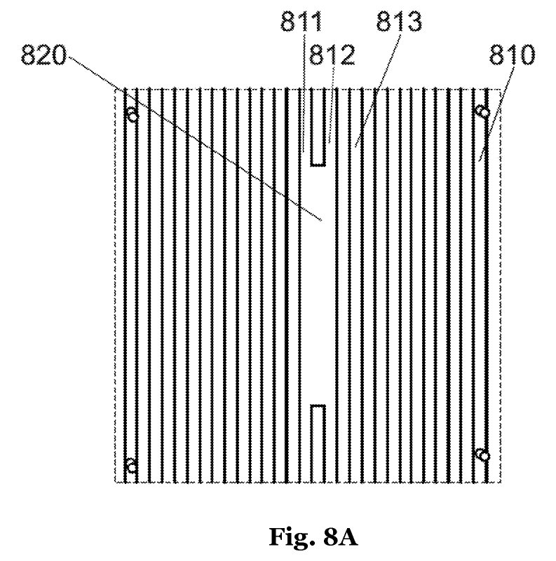

FIGS. 7A and 7B show an illustrative SEM image of a “lines-and-spaces” pattern of a lithography mask in top view.

FIG. 7A shows a “lines-and-spaces” pattern in which two “lines” 710 were connected to one another by excess material. This section 720 was subjected to a repair operation, with particle beam-based removal of this excess material. Subsequently, the repaired section 720 was passivated by a method according to the invention as described herein.

FIG. 7B shows an analogously repaired “lines-and-spaces” pattern with a repair region 720, except that this was not passivated subsequently. By comparison with FIG. 7A, it can be stated that, after a few further repair cycles that have been executed, for example, in an environment of the repair region 720, the repair site was subject to degradation caused by unwanted progression of the repair process. This can lead to a variance from a desired repair outcome.

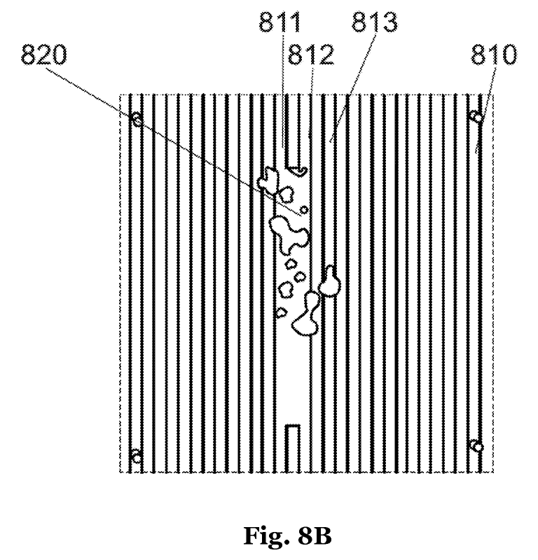

FIGS. 8A and 8B show illustrative SEM images of an illustrative “lines-and-spaces” pattern in top view.

FIG. 8A shows a partial repair of a defect 820 that had connected three of the “lines” 810, namely “lines” 811, 812 and 813, to one another. The defect 820 was removed between the “lines” 812 and 813 by use of a repair operation.

In order to protect the repair site from unwanted progression of the repair operation, a border of the repair region was subjected to a passivating operation according to the invention, where the passivation region was drawn in a linear manner around the repair region with a width of ± 5 nm, specifically with 200 passivation passes. As apparent from FIG. 8A, after the passivating operation had ended, there was no longer any significant progression of the repair in the repair region, nor any other significant degradation.

By contrast, FIG. 8B shows a similar defect 820 that was repaired in a similar way, except that only 100 passivation passes were conducted. As apparent in FIG. 8B, considerable degradation of the “lines-and-spaces” pattern was found after the repair (for example, by comparison with FIG. 8A). This is attributed to the fact that the passivation was not conducted to a sufficient degree.

It can thus be stated that, for example, for a width of the linear passivation region of ± 5 nm and 100 passivation passes, the result was still unsatisfactory durability of the repair region. If the number of passivation passes is increased to 200, by contrast, it is already clearly apparent that the repair region has become durable.

In some examples, the mask (or more generally sample) is not necessarily processed. For example, it may also be merely examined. Both for examination and for processing (e.g., deposition and/or etching), both of which may be effected in a particle beam-based manner, it may be necessary to use reference markings on the sample. These may be used, for example, for orientation and/or drift control. However, as soon as the particle beam hits the reference markings, the latter may be worn away. It may therefore be advisable to passivate reference markings present on the sample and/or reference markings deposited or etched thereon as described herein in relation to a repair region. For instance, the reference markings may be protected in a sustainably usable manner and from harmful and unwanted etching processes that may be conducted on the mask, and other adverse effects.

A brief (non-exhaustive) overview of possible passivation gases and, if appropriate, possible added gases is to be given hereinafter.

Useful (non-exhaustive) examples of possible passivation gases may include (metal, transition element, main group) alkyls such as cyclopentadienyl (Cp)- or methylcyclopentadienyl (MeCp)-trimethylplatinum (CpPtMe₃ or MeCpPtMe₃), tetramethyltin SnMe4, trimethylgallium GaMe₃, ferrocene Cp₂Fe, bisarylchromium Ar₂Cr and other such compounds. It is likewise possible to use (metal, transition element, main group) carbonyls such as chromium hexacarbonyl Cr(CO)₆, molybdenum hexacarbonyl Mo(CO)₆, tungsten hexacarbonyl W(CO)6, dicobalt octacarbonyl Co₂(CO)₈, triruthenium dodecacarbonyl Ru₃(CO)₁₂, ruthenocene Cp₂Ru, iron pentacarbonyl Fe(CO)₅ and other compounds of this kind. Additionally or alternatively, it is possible to use (metal, transition element, main group) alkoxides such as tetraethoxysilane Si(OC₂H₅), tetraisopropoxytitanium Ti(OC₃H₇)₄ and other such compounds. In addition, it is possible to use (metal, transition element, main group) halides such as WF₆, WCl₆, TiCl₆, BCl₃, SiCl₄ and other such compounds. It is also possible to use (metal, transition element, main group) complexes such as copper bis(hexafluoroacetylacetonate) Cu(C₅F₆HO₂)₂, dimethylgold trifluoroacetylacetonate Me₂Au(C₅F₃H₄O₂) and other such compounds. Additionally or alternatively, it is also possible to use organic compounds such as CO, CO₂, aliphatic or aromatic hydrocarbons, constituents of vacuum pump oils, volatile organic compounds and other such compounds.

Useful gases that can be added to the passivation gas include, for example, oxidants such as, for example and non-exhaustively, O₂, O₃, H₂O, H₂O₂, N₂O, NO, NO₂, HNO₃ and other oxygen-containing gases. Additionally or alternatively, gases that can be added may also contain halides such as Cl₂, HCl, XeF₂, HF, I₂, HI, Br₂, HBr, NOCl, PCl₃, PCl₅, PF₃ and other halogen-containing gases. Additionally or alternatively, the gases that can be added may also contain gases having reducing action such as H₂, NH₃, CH₄ and other hydrogen-containing gases.

What is claimed is:

1. A method of passivating a repair region of a lithography mask, comprising:
a) feeding in a passivation gas; and
b) directing a particle beam onto a passivation region of the mask, where the passivation region has at least one section outside the repair region.

2. The method according to claim 1, further comprising:
feeding in a repair gas before feeding in the passivation gas and directing the particle beam onto the repair region in the presence of the repair gas to repair a defect in the repair region.

3. The method according to claim 1, wherein the passivation region also has at least one section in the repair region.

4. A method of repairing a lithography mask, comprising:
a) particle beam-based repair of a defect in a repair region of the mask in the presence of a repair gas;
b) subsequent passivating of the repair region in a passivation region in the presence of a passivation gas, wherein the passivating is preferably effected in a particle beam-based manner.

5. The method according to claim 1, wherein the passivation region completely covers the repair region.

6. The method according to claim 1, wherein the passivation region has a greater area content than the repair region.

7. The method according to claim 1, wherein the passivation region extends at least partly along an edge section of the repair region.

8. The method according to claim 1, wherein the repair region is at least partly bounded from a non-repaired region by a border and/or a circumferential edge.

9. The method according to claim 8, wherein the passivation region at least partly includes the border and/or the circumferential edge.

10. The method according to claim 8, wherein the passivation region has at least one section having a width between 2 and 150 nm that extends beyond the border and/or the circumferential edge.

11. The method according to claim 1, wherein the passivation region has at least one section having a width of 2 to 150 nm that extends into the border and/or the circumferential edge.

12. The method according to claim 1, wherein there is no passivation in at least one section of the repair region.

13. The method according to claim 1, wherein the passivation gas has a first component including Si and/or O.

14. The method according to claim 13, wherein the first component comprises a tetraethoxysilane, TEOS.

15. The method according to claim 13, wherein the passivation gas has a second component comprising N and/or O, preferably NO₂.

16. The method according to claim 2, wherein the defect has a defect with excess material of an absorbing and/or phase-shifting material.

17. The method according to claim 2, wherein the repair puts the mask in an on spec condition in an environment of the repair region.

18. The method according to claim 1, wherein a passivation layer is deposited in the passivation region in the presence of the particle beam and the passivation gas and is preferably Si- and/or O-containing.

19. The method according to claim 18, wherein the deposited layer has an SiₓO_{y}C_{z} layer.

20. The method according to claim 18, wherein the deposition of the passivation layer does not significantly affect the specification of the mask.

21. The method according to claim 18, wherein a thickness of the passivation layer is in a range from 1 to 15 nm.

22. The method according to claim 18, wherein the deposited passivation layer has a complex refractive index having a smaller real part and/or imaginary part than a real part and/or imaginary part of a complex refractive index of a material of a pattern element of the mask.

23. The method according to claim 18, wherein the deposited passivation layer is not significantly affected by at least five, preferably at least ten, further repair cycles on the mask.

24. A computer program comprising code which, when executed, performs the method according to claim 1.

25. A device for passivating a repair region of a lithography mask, comprising:
a) means of feeding in a passivation gas; and
b) means of directing a particle beam onto a passivation region, where the passivation region has at least one section outside the repair region.

26. The device according to claim 25, further comprising:
means of automatically executing a method of passivating the repair region of the lithography mask, the method comprising:
feeding in the passivation gas; and
directing the particle beam onto the passivation region of the mask, where the passivation region has at least one section outside the repair region.

27. A device for repairing a lithography mask, comprising:
a) means of particle beam-based repair of a defect in a repair region of the mask in the presence of a repair gas; and
b) means of subsequently passivating the repair region in a passivation region and in the presence of a passivation gas, wherein the passivating is preferably effected in a particle beam-based manner.

28. The device according to claim 27, further comprising:
means of automatic execution of the subsequent passivation after the particle beam-based repair has ended.

29. The device according to claim 27, further comprising:
means of automatic execution of a method of passivating the repair region of the lithography mask, the method comprising:
feeding in the passivation gas; and
directing a particle beam onto the passivation region of the mask, where the passivation region has at least one section outside the repair region;
wherein the passivation region also has at least one section in the repair region.

30. The device according to claim 25, further comprising:
means of determining the passivation region based on an expansion of the repair region.

31. The device of claim 25, further comprising a computer program comprising code which, when executed, performs a method of passivating the repair region of the lithography mask, the method comprising:
feeding in the passivation gas; and
directing the particle beam onto the passivation region of the mask, where the passivation region has at least one section outside the repair region.
